(19) United States
(12) Patent Application Publication
(10) Pub. No.: US 2024/0244772 A1
(43) Pub. Date: Jul. 18, 2024

(54) DYNAMICALLY CONTROLLING ELECTRONIC DEVICE OPEN AIR PATIO (OAR) USING ADJUSTABLE THERMAL VENTING MECHANISMS

(71) Applicant: Intel Corporation, Santa Clara, CA (US)

(72) Inventors: Smit Kapila, Bangalore (IN); Jeff Ku, Taipei (TW); Min Suet Lim, Penang (MY); Sarma Vmk Vedhanabhatla, Bengaluru (IN)

(21) Appl. No.: 18/619,554

(22) Filed: Mar. 28, 2024

(51) Int. Cl. H05K 5/02

(52) U.S. Cl. CPC H05K 5/0213

(57) ABSTRACT

Techniques are described to dynamically adjust the open air ratio (OAR) while ensuring compliance with regulatory requirements. An adjustable thermal vent assembly is described that dynamically adjusts the OAR for inlet/outlet vents depending on the current use case. The adjustable thermal vent assembly functions to increase the grating spacing only when a triggering condition is met that ensures that a corresponding thermal vent location is inaccessible. Such temporarily inaccessible regions may include the bottom cover of an electronic device when positioned on the surface of an object, for thermal intake vents, or the rear portion of an electronic device when the display cover exceeds a predetermined angle, for thermal exhaust vents.

### TECHNICAL FIELD

The disclosure is directed generally to an adjustable thermal vent assembly and, in particular, to an adjustable thermal vent assembly that uses detected triggering conditions to actuate a movable shutter plate to adjust the open air ratio (OAR) of a thermal vent while ensuring compliance with regulatory safety requirements.

### BACKGROUND

Electronic devices often utilize thermal vents to facilitate proper air flow. For example, laptops often implement thermal intake vents on the bottom cover or “D cover,” and implement thermal exhaust vents at the rear cover. These thermal vents typically comprise gratings that have a fixed spacing. However, safety regulations restrict the size of these grating spacings, or gaps, as such regulatory requirements forbid any rod-shaped object with a diameter greater than 1 mm to be openly inserted into the system through any opening. As a result, to meet these requirements, conventional thermal vent designs are restricted to an open air ratio (OAR) of about 40-50%. This restricted OAR, in turn, impacts the air flow and limits the thermal performance, eventually limiting system performance due to restricted thermal design power (TDP).

### BRIEF DESCRIPTION OF THE DRAWINGS/FIGURES

The accompanying drawings, which are incorporated herein and form a part of the specification, illustrate the present disclosure and, together with the description, further serve to explain the principles and to enable a person skilled in the pertinent art to make and use the techniques discussed herein.

In the drawings, like reference characters generally refer to the same parts throughout the different views. The drawings are not necessarily to scale, emphasis instead generally being placed upon illustrating the principles of the disclosure. In the following description, reference is made to the following drawings, in which:

FIG. 1 illustrates a thermal vent associated with an adjustable thermal vent assembly, in accordance with the disclosure;

FIG. 2 illustrates additional details of an adjustable thermal vent assembly, in accordance with the disclosure;

FIG. 3A illustrates an adjustable thermal vent assembly with a movable shutter plate in a default position, in accordance with the disclosure;

FIG. 3B illustrates an adjustable thermal vent assembly with the movable shutter plate in a second position, in accordance with the disclosure;

FIG. 4A illustrates details of a trigger mechanism and its interaction with a latch mechanism corresponding to the movable shutter plate being in a default position, in accordance with the disclosure;

FIG. 4B illustrates details of a trigger mechanism and its interaction with a latch mechanism corresponding to the movable shutter plate being in a second position, in accordance with the disclosure;

FIG. 5A illustrates a top down view of a movable shutter plate in a default position when a triggering condition has not been met, in accordance with the disclosure;

FIG. 5B illustrates a top down view of the movable shutter plate in a second position when the triggering condition has been met, in accordance with the disclosure;

FIG. 6A illustrates an outer view of an electronic device showing a movable shutter plate in a second position, in accordance with the disclosure;

FIG. 6B illustrates an inner view of an electronic device showing the movable shutter plate in a second position, in accordance with the disclosure;

FIG. 7 illustrates a bottom cover of an electronic device showing two adjustable thermal vent assemblies, each having a respective movable shutter plate in the second position, in accordance with the disclosure;

FIG. 8A illustrates an implementation of the adjustable thermal vent assembly for a rear cover of an electronic device for a scenario in which the triggering condition has not been met, in accordance with the disclosure;

FIG. 8B illustrates an implementation of the adjustable thermal vent assembly for a rear cover of an electronic device for a scenario in which the triggering condition has been met, in accordance with the disclosure;

FIGS. 9A and 9B illustrate the result of thermal simulations for the use of adjustable thermal vent assemblies in an electronic device, in accordance with the disclosure;

FIG. 10 illustrates an electronic device, in accordance with the disclosure; and

FIG. 11 illustrates a process flow, in accordance with the disclosure.

The present disclosure will be described with reference to the accompanying drawings. The drawing in which an element first appears is typically indicated by the leftmost digit(s) in the corresponding reference number.

### DETAILED DESCRIPTION

The following detailed description refers to the accompanying drawings that show, by way of illustration, exemplary details in which the disclosure may be practiced. In the following description, numerous specific details are set forth in order to provide a thorough understanding of the present disclosure. However, it will be apparent to those skilled in the art that the various designs, including structures, systems, and methods, may be practiced without these specific details. The description and representation herein are the common means used by those experienced or skilled in the art to most effectively convey the substance of their work to others skilled in the art. In other instances, well-known methods, procedures, components, and circuitry have not been described in detail to avoid unnecessarily obscuring the disclosure.

### I. Adjustable Thermal Vent Configuration and Functionality

Again, conventional thermal vents implicitly restrict OAR to ensure compliance with regulatory requirements. More specifically, the grating spacings associated with conventional thermal vents need to be less than one millimeter such that a one millimeter rod cannot be openly inserted between the grating spaces. However, the regulatory requirements also consider the context and the current use case when determining compliance. For example, such regulations only require that a one millimeter rod cannot be “openly” inserted into any opening, grating, apertures, etc., of an electronic device so as to not damage fans or other internal components, which could pose a safety hazard.

In this context, “openly inserted” means that a particular opening must be openly and readily accessible. The adjustable thermal vent assembly as discussed herein leverages this requirement to dynamically adjust the OAR for intake and/or exhaust vents depending on the use case. The adjustable thermal vent assembly accomplishes this by increasing the grating spacing only when a triggering condition is met, which ensures that a corresponding thermal vent location is inaccessible with respect to the insertion of a one millimeter diameter rod. In other words, the adjustable thermal vent assembly as described herein may increase the grating spacing beyond a one millimeter pitch when a corresponding region of the electronic device is temporarily inaccessible. Such temporarily inaccessible regions may include, in some non-limiting and illustrative scenarios as discussed in further detail herein, the bottom cover thermal intake vents of a laptop when positioned on the surface of an object, the rear cover thermal exhaust vents of a laptop upon the display cover exceeding a predetermined angle, etc.

The adjustable thermal vent assembly is discussed herein with respect to compliance with regulatory requirements that use a one millimeter diameter rod as a test standard. However, the adjustable thermal vent assembly is not limited to the specific dimensions as discussed herein, which are provided for ease of explanation. The adjustable thermal vent assembly as discussed herein may utilize gratings or other components having any suitable size and/or shape, which may include the grating spacing. Furthermore, the adjustable thermal vent assembly is discussed herein with respect to a thermal vent positioned on the bottom or rear of an electronic device such as a laptop. However, this is also provided for ease of explanation and not limitation, as the adjustable thermal vent assembly as discussed herein may be implemented in accordance with any suitable electronic component that may benefit from a dynamically adjustable OAR, and may be disposed at any location within such electronic devices.

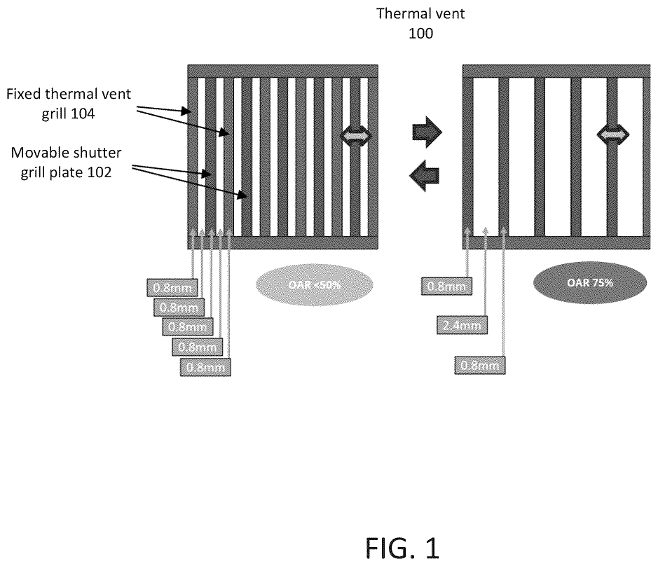

FIG. 1 illustrates a thermal vent associated with an adjustable thermal vent assembly, in accordance with the disclosure. The thermal vent 100 comprises an adjustable portion, referred to herein as a movable shutter grill plate 102 or simply as a movable shutter plate 102, and a fixed portion, referred to herein as a fixed thermal vent grill 104 or simply as thermal vent grill 104. The thermal vent grill 104 may be identified with any suitable location of an electronic device, such as an opening on the bottom or rear of a laptop, as discussed in further detail herein. Furthermore, the thermal vent 100 may be identified with any suitable portion of an airflow system for any suitable type of electronic device, such as an air intake or air exhaust vent. The thermal vent grill 104 may be identified with a grating or grill pattern that is machined or cut away from any suitable portion of an electronic device. Alternatively, the thermal vent grill 104 may be implemented as a modular component that is inserted and/or attached to an electronic device as part of a manufacturing assembly process.

In any event, the thermal vent grill 104 is a static component comprising a grating having any suitable grating spacing. When the grating spacings, or gaps, are uniform, i.e. equal to one another, the grating spacing may alternatively be referred to as a grating pitch. The grating spacing or pitch, as the case may be, is thus defined as the dimension of the gaps, or spaces, between the solid portions of the thermal vent grill 104. As shown in FIG. 1, the thermal vent grill 104 has a spacing, or pitch in this scenario, of 2.4 mm, which is three times that of the 1 mm diameter rod used for regulatory safety tests as noted above.

The movable shutter plate 102 is configured to fit over the thermal vent grill 104 as shown in FIG. 1 such that the movable shutter plate 102 and the thermal vent grill 104 overlap and are aligned with one another in one position of the movable shutter plate, which is illustrated in FIG. 1 as the increased OAR case of 75%. The movable shutter plate 102 may likewise comprise a grating having any suitable grating spacing, which again may be referred to as a grating pitch when the grating spacings are uniform. For the non-limiting and illustrative scenarios as shown in FIG. 1 and throughout the remainder of this disclosure, the movable shutter plate 102 and the thermal vent grill 104 have uniform grating spacings, i.e. grating pitches, that are equal to one another. However, the movable shutter plate 102 and the thermal vent grill 104 may alternatively have non-uniform grating spacings and/or be different than one another.

Thus, and as shown in FIG. 1, the movable shutter plate 102 also has a grating spacing, or pitch in this scenario, of 2.4 mm, which again is three times that of the 1 mm diameter rod used for regulatory safety tests as noted above. The movable shutter plate 102 is configured to be actuated, i.e. moved, with respect to the thermal vent grill 104. For the non-limiting and illustrative scenarios as further discussed herein, the movable shutter plate 102 is moved between two different preset positions, which are shown in FIG. 1, each being associated with a respective OAR value for the thermal vent 100. In the first position as shown on the left side of FIG. 1 and associated with the lower OAR value, the movable shutter plate 102 is in a first position such that the grating of the movable shutter plate 102 is interspaced between the grating of the thermal vent grill 104, thereby forming an overlapping grating spacing.

As shown in FIG. 1, due to the dimensions of the grating spacings of the movable shutter plate 102 and the thermal vent grill 104, the overlapping grating spacing, or pitch in this scenario, is 0.8 mm, which is less than the 1 mm diameter rod used for regulatory safety tests as noted above. Thus, this position of the movable shutter plate 102 may be identified with a default position that may be implemented when a previous triggering condition has no longer been met or when another, different triggering condition has been met, as discussed in further detail below. In this position of the movable shutter plate 102, the overlapping grating spacing allows the thermal vent 100 to pass the 1 mm diameter rod insertion test, albeit with a reduced OAR.

That is, the grating spacings of the grating of the movable shutter plate 102 and the thermal vent grill 104 may comprise equal grating pitches, which are greater than about (e.g. within 1%, 2%, 5%, 10%, 20%, etc.) one millimeter, as shown by the Figure on the right side in FIG. 1. However, when the two grating pitches overlap with one another as shown in the left side of FIG. 1, the resulting overlapping grating spacing formed in this manner comprises a pitch that is less than about (e.g. within 1%, 2%, 5%, 10%, 20%, etc.) one millimeter.

Thus, the triggering condition that causes the actuation of the movable shutter plate 102 from the default position to the second, increased OAR position may represent any suitable type and/or number of conditions, and may be referred to herein as “initial” triggering condition(s) or simply as triggering condition(s). The triggering condition(s) may thus represent any suitable condition(s) that ensure that the thermal vent 100 is inaccessible for the purpose of passing the 1 mm diameter rod insertion test. Thus, the triggering condition being met may be the act of and/or the detection of a specific use case of an electronic device that ensures inaccessibility to the thermal vent 100. Again, a non-limiting and illustrative scenario for such a use case may be the thermal vent 100 being on the bottom of an electronic device that is placed onto the surface of an object, thereby impeding access to the thermal vent 100. Another non-limiting and illustrative scenario for such a use case may be the thermal vent 100 being at the rear of a laptop and the display lid being moved to a point at which access to the thermal vent 100 is impeded.

In any event, upon the triggering condition(s) being met, the movable shutter plate 102 is actuated to the second position, as represented in FIG. 1 by the higher OAR value. In this position, the overlapping grating spacing is increased compared to the movable shutter plate being in the default position. This allows for an increase in OAR value via the increased overlapping grating spacing of 2.4 mm while still ensuring compliance with regulatory safety requirements, as the thermal vent 100 is inaccessible in this scenario in light of the triggering condition(s) being met, as noted above.

Although FIG. 1 illustrates the movable shutter plate 102 being actuated between a first (default) and a second position, which is also referenced throughout this disclosure, it is noted that this is a non-limiting and illustrative scenario. The movable shutter plate 102 may be actuated from the default position to ensure compliance with regulatory safety testing to any suitable number of additional preset positions. Thus, the right side Figure in FIG. 1 may represent a maximum OAR value that is identified with a largest overlapping grating spacing of 2.4 mm. However, the movable shutter plate 102 may be moved to additional positions in which the overlapping grating spacing is between the values as shown in in FIG. 1 (not shown) to facilitate incremental increases in the OAR value that is less than this maximum value. Moreover, although the movable shutter plate 102 is discussed herein as being actuated in a straight line, i.e. one-dimension, this is also a non-limiting and illustrative scenario, as the movable shutter plate 102 may be actuated in any suitable number of dimensions in response to a triggering condition being met.

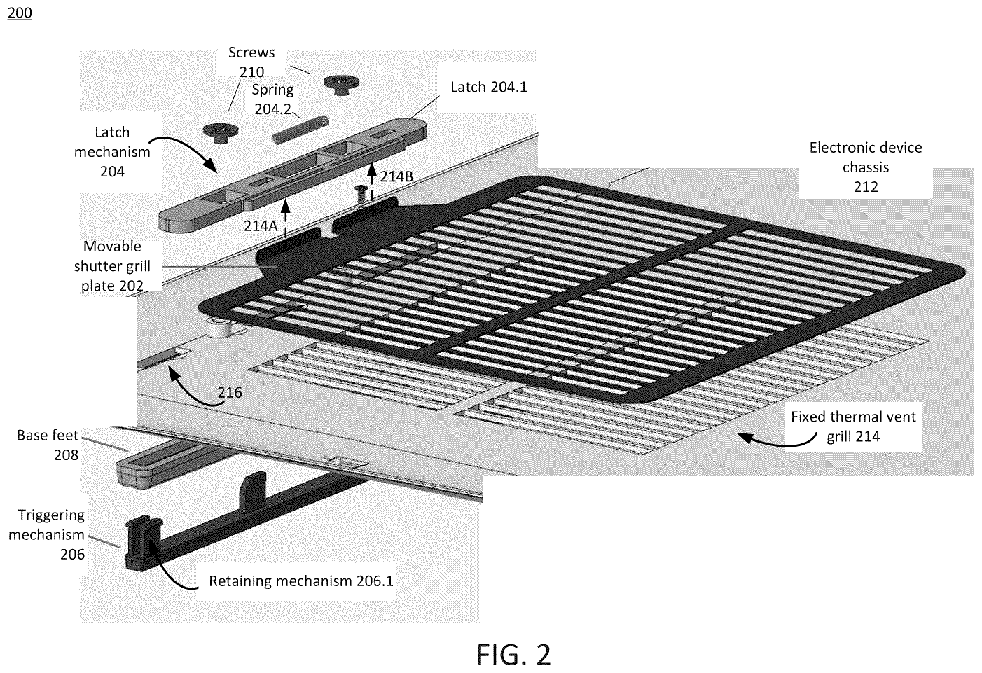

FIG. 2 illustrates additional details of an adjustable thermal vent assembly, in accordance with the disclosure. The adjustable thermal vent assembly as shown in FIG. 2 also comprises a movable shutter grill plate 202 and a fixed thermal vent grill 214, which may be identified with the movable shutter grill plate 102 and the fixed thermal vent grill 104, respectively, as shown and described above with respect to FIG. 1. Also, and as noted above with respect to FIG. 1, the movable shutter grill plate 202 and the fixed thermal vent grill 214 may alternatively be referred to herein simply as a movable shutter plate 202 and a thermal vent grill 214, respectively. For the non-limiting and illustrative scenario as shown in FIG. 2, the thermal vent grill 214 is disposed in an portion of an electronic device chassis 212, which may represent the bottom cover of an electronic device, such as the D cover of a laptop computer. The movable shutter plate 202 as shown in FIG. 2 is coupled to the inside of the electronic device chassis 212, with the base feet 208 being disposed on the outer surface of the electronic device chassis 212, i.e. the bottom of the electronic device, in this scenario.

The adjustable thermal vent assembly further comprises a latch mechanism 204 and a triggering mechanism 206. The latch mechanism 204 comprises a latch 204.1 and a spring 204.2. The movable shutter plate 202, the latch 204.1, the spring 204.2, and the triggering mechanism 206 may comprise any suitable material to ensure durability and a high number of actuation cycles. To provide some non-limiting and illustrative scenarios, the movable shutter plate 202 and the spring 204.2 may comprise stainless steel. Moreover, the latch 204.1 and the triggering mechanism 206 may comprise a polymer, a thermoplastic, polyoxymethylene (POM), etc.

The latch 204.1 may be coupled to the movable shutter plate 202 via any suitable connection and/or bond, such as a friction fit connection, an adhesive bond, etc. The movable shutter plate 202 may comprise tabs for this purpose, which are inserted into mating slots in the latch 204.1 as shown in FIG. 2 by way of the arrows 214A, 214B. The latch mechanism 204 is coupled to the electronic device chassis 212 via the screws 210, which remain fixed and retain the latch 204.1 without impeding the movement of the latch mechanism 204.1 while coupled to the movable shutter plate 202.

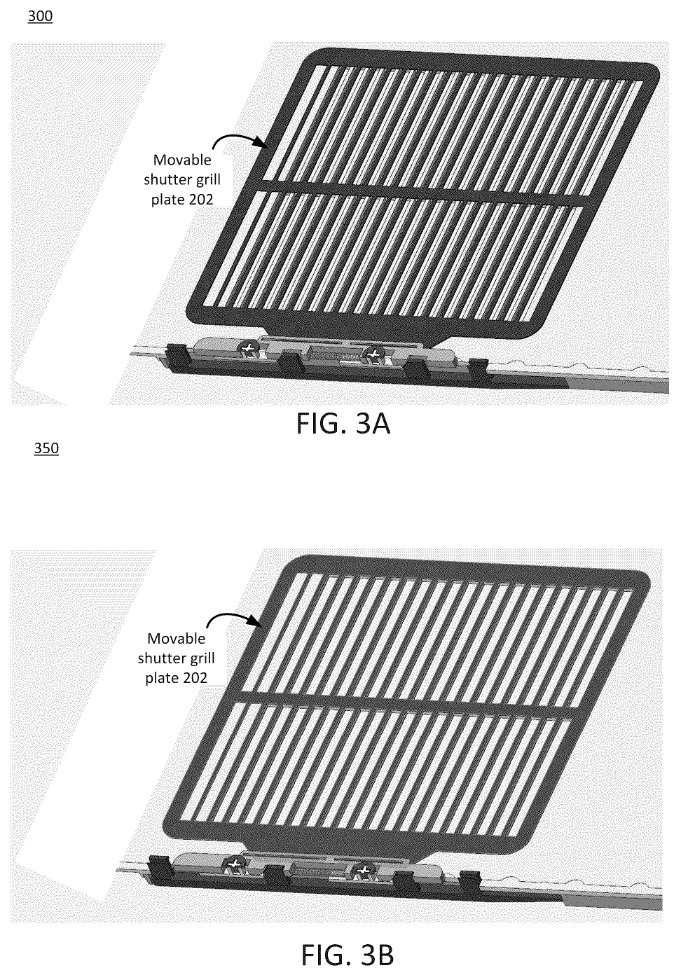

The adjustable thermal vent assembly further comprises a triggering mechanism 206. Thus, the movable shutter plate 202 is actuated from the first (i.e. default) position to the second position via actuation of the latch mechanism 204.1 by the triggering mechanism 206. This is further illustrated in FIGS. 3A and 3B, which show assembled views of the adjustable thermal vent assembly as shown in FIG. 2, with like component reference numerals being omitted with the exception of the movable shutter plate 202 as shown. Specifically, FIG. 3A illustrates the adjustable thermal vent assembly with the movable shutter plate 202 in a default position, whereas FIG. 3B illustrates the adjustable thermal vent assembly with the movable shutter plate 202 in the second position. The default position of the movable shutter plate 202 as shown in FIG. 3A corresponds to the smaller overlapping grating spacing and smaller OAR, as shown and discussed with respect to FIG. 1. However, the second position of the movable shutter plate 202 as shown in FIG. 3B corresponds to the larger overlapping grating spacing and larger OAR as shown and discussed with respect to FIG. 1.

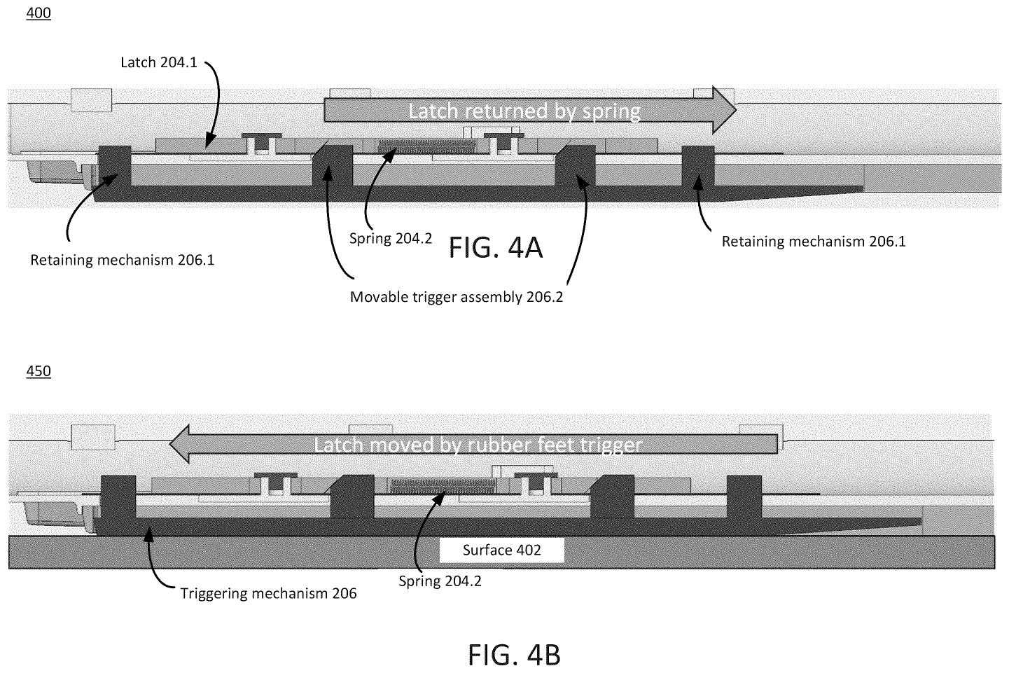

To perform the actuation of the latch mechanism 204, and in turn the actuation of the coupled movable shutter plate 202, the latch mechanism 204 comprises a spring 204.2 that is configured to bias the movable shutter plate 202 to the first (i.e. default) position when an initial triggering condition is not met. In this non-limiting and illustrative scenario, the triggering condition is with respect to the electronic device chassis 212 being placed on a surface of an object. This is shown in further detail with respect to FIGS. 4A and 4B. Thus, FIG. 4A illustrates details of the trigger mechanism 206 and its interaction with the latch mechanism 204 corresponding to the movable shutter plate 202 being in the default position. FIG. 4B illustrates details of a trigger mechanism 206 and its interaction with the latch mechanism 204 corresponding to the movable shutter plate 202 being in the second position.

To perform the actuation of the latch mechanism 204, the triggering mechanism 206 comprises one or more retaining mechanisms 206.1, as shown in FIG. 2 and FIGS. 4A-B, which is coupled to the electronic device chassis 212 as shown in FIG. 2 via a mating slot 216. Only a single retaining mechanism 206.1 is shown in FIG. 2 so as to not clutter the diagram. The retaining mechanism(s) 206.1 may pass through the base feet 208 and captivate the triggering mechanism 206 to the electronic device chassis 212 by way of this coupled arrangement. The retaining mechanism 206.1 may thus form a friction fit with the electronic device chassis 212 to prevent the triggering mechanism 206 from falling out of the electronic device chassis 212 due to gravity. However, the retaining mechanism(s) 206.1 may ensure that the triggering mechanism 206 is still actuated upwards with respect to its orientation in FIG. 2 with respect to the electronic device chassis 212.

For actuation of the latch mechanics 204, the triggering mechanism 206 may also comprise a movable trigger assembly 206.2 that is configured to engage with the latch mechanism 204 via engagement with the latch 204.1. Upon engagement, the movable trigger assembly 206.2 causes the latch mechanism 204 to move in response to a compressible force being applied to the triggering mechanism 206. Thus, the triggering condition is met when the compressible force is applied to the movable trigger assembly 206.2 exceeding a predetermined threshold value, which is shown in FIG. 4B as the result of placing the electronic device onto a surface 402.

In the non-limiting and illustrative scenario as shown in FIGS. 4A-4B, the movable trigger assembly 206.2 comprises a number of teeth that engage with mating teeth in the latch 204.1 of the latch mechanism 204. Due to the shape of the teeth in the movable trigger assembly 206.2 and the latch 204.1, placement of the electronic device onto the surface 402 overcomes the biasing force applied by the spring 204.2, and results in movement of the latch mechanism 204 from the default position as shown in FIG. 4A to the position as shown in FIG. 4B. When the electronic device is moved from the surface 402 as shown in FIG. 4A, the teeth in the movable trigger assembly 206.2 retract from the latch 204.1 to allow the biasing force of the spring 204.2 to once again move the latch mechanism 204 into the default position, as shown in FIG. 4A. Again, the position of the latch mechanism 204 as shown in FIGS. 4A and 4B corresponds to the position of the movable trigger assembly 206.2 as shown in FIGS. 3A and 3B, respectively.

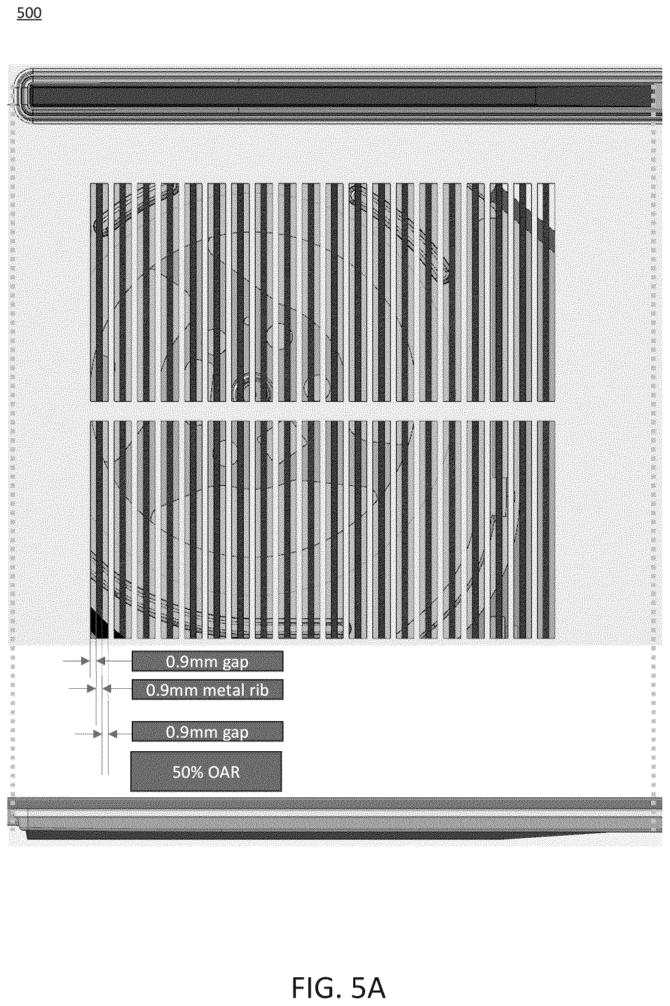

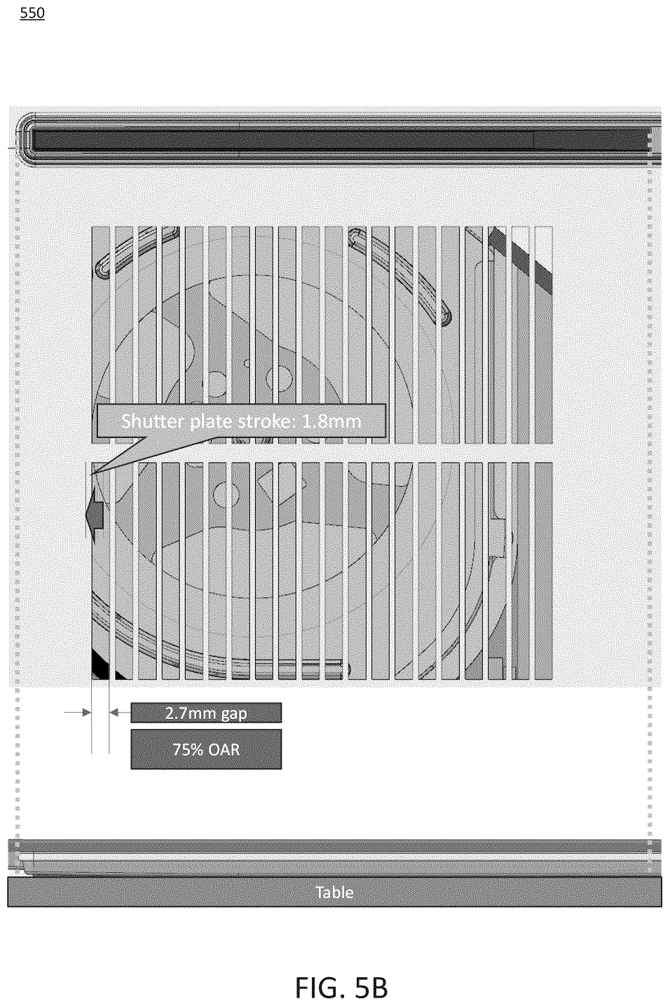

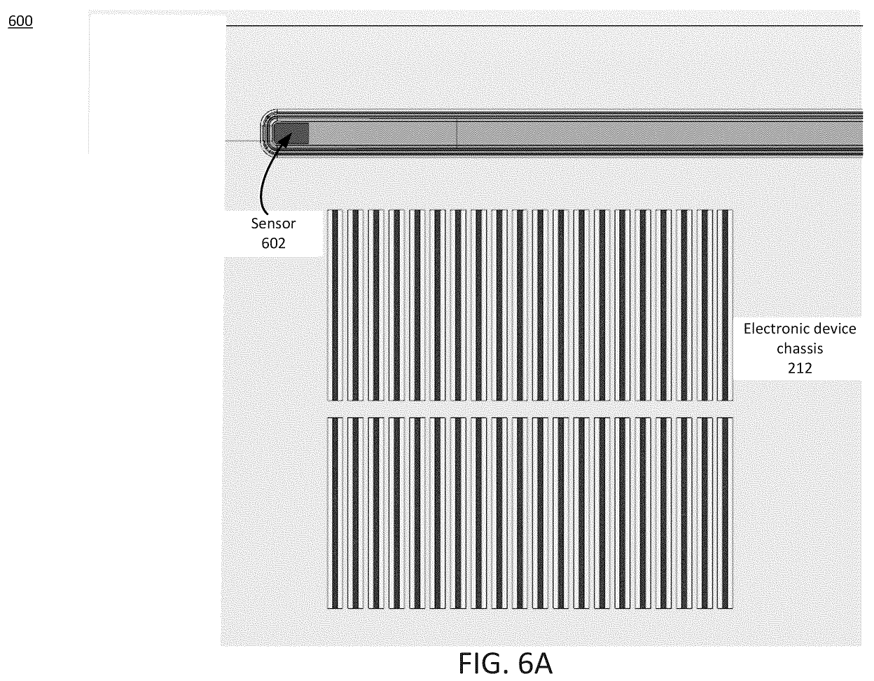

Again, the adjustable thermal vent assembly as discussed herein may utilize gratings or other components having any suitable size and/or shape, which may include the grating spacing. An additional non-limiting and illustrative scenario is shown in this regard with respect to FIGS. 5A and 5B. For instance, FIG. 5A illustrates a top down view of the movable shutter plate 202 in the default position, i.e. when the triggering condition has not been met, whereas FIG. 5B illustrates a top down view of the movable shutter plate 202 in the second position when the triggering condition has been met. The triggering condition for the movable shutter plate 202 as shown in FIGS. 5A and 5B is the same as that discussed above with respect to FIGS. 4A and 4B. However, the pitch or gap spacing of the grating of the movable shutter plate 202 and the thermal vent grill 214 for the adjustable thermal vent assembly as shown in FIG. 5A and 5B is increased from 0.8 mm to 0.9 mm. The movable shutter plate 202 thus has a corresponding linear actuation or “stroke” of 1.8 mm to facilitate the overlapping grating spacing increasing from 0.9 mm (reduced OAR) to 2.7 mm (increased OAR).

The adjustable thermal vent assembly as discussed above with respect to FIGS. 2, 3A-3B, 4A-4B, and 5A-5B implements a latch mechanism 204 that is mechanically actuated by way of the compression of the triggering mechanism 206. However, the latch mechanism 204 may alternatively be driven by any suitable electromechanical actuator, i.e. electromechanically actuated. In such a case, the latch mechanism 204 may comprise such an electromechanical actuator instead of the spring 204.2. The electromechanical actuator may thus actuate the movable shutter plate 202 between the default position and the second position in response to one or more triggering conditions being met.

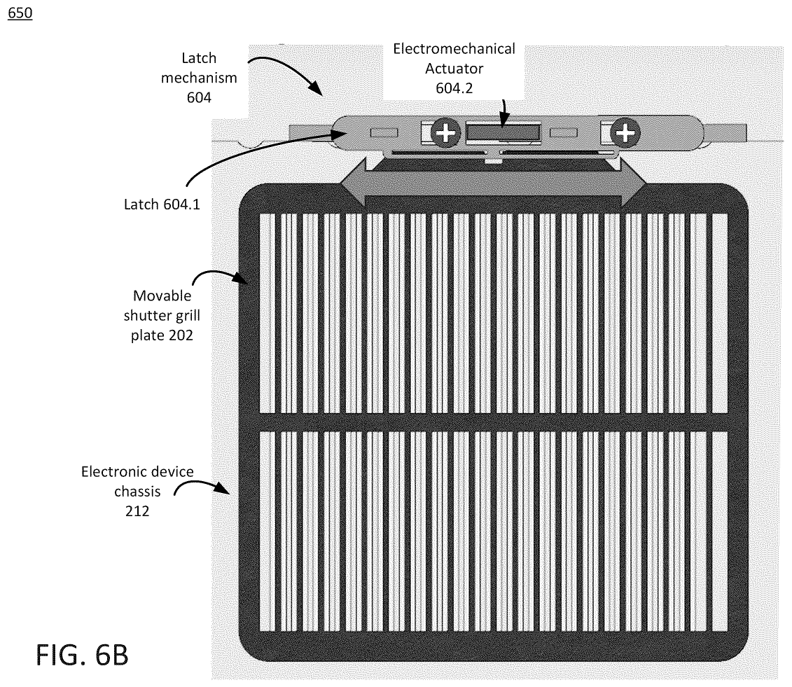

The use of an electromechanical actuator instead of the spring 204.2 is described with respect to FIGS. 6A and 6B. Both FIGS. 6A and 6B illustrate the movable shutter 202 in the second position in response to a triggering condition being met. FIG. 6A illustrates an outer view of (i.e. external to) the electronic device as discussed herein, whereas FIG. 6B illustrates an inner view of (i.e. internal to) the electronic device as discussed herein. The components as shown and discussed with respect to FIGS. 6A and 6B are identical to analogous components discussed above, and thus only differences between these components are further discussed herein.

For instance, and as shown in FIG. 6B, the adjustable thermal vent assembly comprises a latch mechanism 604 instead of the latch mechanism 204 as shown in FIG. 2. The latch mechanism 604 may be identical or substantially similar in shape, material, and/or function as the latch mechanism 204, although the latch mechanism 604 comprises an electromechanical actuator 604.2 instead of the spring 204.2. The electromechanical actuator 604.2 may be implemented as any suitable type of device configured to actuate the latch 604.1, and thus the coupled movable shutter plate 202, in response to any suitable type of control signal. In an non-limiting and illustrative scenario, the electromechanical actuator 604.2 may comprise a solenoid.

Thus, when the electromechanical actuator 604.2 is implemented for actuation of the movable shutter plate 202, the adjustable thermal vent assembly also comprises a different type of triggering mechanism than the triggering mechanism 206. In a non-limiting and illustrative scenario, the adjustable thermal vent assembly may alternatively implement one or more sensors as the triggering mechanism 206, such as the sensor 602 as shown in FIG. 6, and the triggering condition may be met based upon the sensor data that is generated via these sensors. Such sensors may be implemented as any suitable number and/or type of sensors configured to generate sensor data, from which a particular use case may be detected as the triggering condition that is met.

In a non-limiting and illustrative scenario, the sensor(s) may comprise one or more proximity sensors, such as an inductive proximity sensor, an optical proximity sensor, a capacitive proximity sensor, a magnetic proximity sensor, an ultrasonic proximity sensor, a photoelectric proximity sensor, etc. The sensor data may represent any suitable representation such as analog, digital, etc., of the respective measurement performed by the proximity sensor based upon the proximity sensor type. Regardless of the number and type of proximity sensors implemented for this purpose, each proximity sensor may thus generate sensor data that is indicative of its proximity to an object.

Thus, the sensor data may indicate the distance of the proximity sensor at a particular location (such as the bottom of an electronic device as discussed above with respect to FIGS. 4A and 4B) to an object and/or an indication that the sensor is within a threshold distance of an object. The sensor data may be provided (such as transmitted via a suitable communication link) to any suitable processing components of the electronic device, which may then analyze the sensor data to determine whether a particular use case has been detected that corresponds to a triggering condition being met. In a non-limiting and illustrative scenario, the use case may be placing the electronic device onto a surface in the same manner as described above with respect to FIG. 4B, such that the triggering condition is met when the sensor data indicates that the proximity sensor is within a threshold distance of an object (i.e. the surface 402). In this case, the processing circuitry may generate one or more control signals that are transmitted to the electromechanical actuator 604.2 to cause actuation of the latch mechanism 604 and, in turn, the movable shutter plate 202.

Furthermore, once the particular use case is no longer present, which may include the removal of the electronic device from the surface 402 in this scenario, the sensor data may indicate this new use case. Thus, the triggering condition is no longer met, and new control signals may then be transmitted to cause the electromechanical actuator 604.2 to re-actuate (or release to an undriven state) the latch 604.1, and thus actuate the coupled movable shutter plate 202, back to the default position. In this way, the electromechanical actuator 604.2 is configured to actuate the latch mechanism 604 to move the movable shutter plate 202 between the default position and the second position based upon sensor data.

Although one sensor 602 is shown in FIG. 6A, which generates sensor data for the determination of a particular use case, this is a non-limiting and illustrative scenario. Alternatively, a particular use case, i.e. a triggering condition, may be determined using any suitable number of sensors to increase the accuracy of the detection of the triggering condition. That is, and to provide another non-limiting and illustrative scenario, the sensor 602 may be one of two sensors, four sensors, etc., which may be the same type of proximity sensors or different types. Each sensor may generate respective sensor data that is received and analyzed by the processing circuitry of the electronic device. The sensor data of multiple sensors may then be used for the determination of whether a particular triggering condition, such as the electronic device being within a threshold distance of the surface 402, has been met. This may include making the determination of the corresponding use case only when the sensor data of each sensor indicates the same information, when a majority of the sensors indicate the same information, etc.

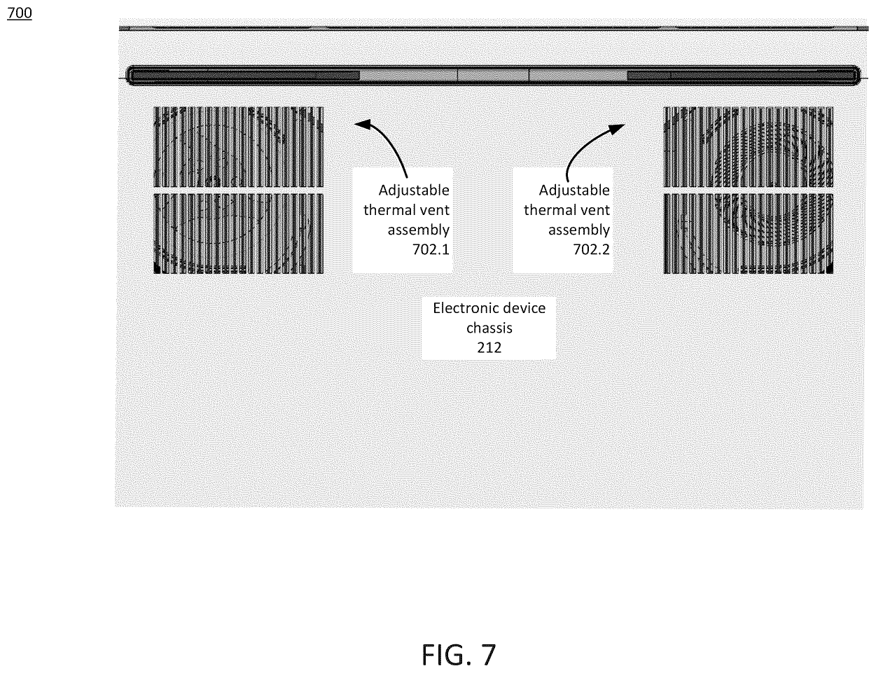

The adjustable thermal vent assembly is described above with respect to a single assembly and a single thermal vent grill. However, an electronic device may implement any suitable number of adjustable thermal vent assemblies, each having a movable shutter plate that covers a respective thermal vent grill. To this end, reference is now made with respect to FIG. 7, which illustrates a bottom cover of an electronic device showing two adjustable thermal vent assemblies, each having a respective movable shutter plate in the default position. The adjustable thermal vent assemblies 702.1, 702.2 may comprise the various components as discussed herein, such as the movable shutter plate 202, the latch mechanism 204/604, the triggering mechanism 206, the sensor 602, etc. Thus, although not shown in the Figures for purposes of brevity, the bottom of the electronic device chassis 212 as shown in FIG. 7 may additionally comprise three, four, or more adjustable thermal vent assemblies 702.

Each of the adjustable thermal vent assemblies 702 may be actuated in response to the same triggering condition or different respective triggering conditions. However, it may be particularly advantageous in terms of simplifying the mechanical design to have each adjustable thermal vent assembly 702 be actuated in response to a respective triggering mechanism, with each of the triggering mechanisms reacting to the same triggering condition being met. Furthermore, each of the adjustable thermal vent assemblies 702 as shown in FIG. 7 are mechanically actuated, such as those described above with respect to FIGS. 2, 3A-3B, 4A-4B, and 5A-5B. However, this is also a non-limiting and illustrative scenario, and the electronic device may implement any suitable combination of mechanically-actuated and/or electromechanically-actuated adjustable thermal vent assemblies.

To provide an illustrative and non-limiting scenario, as noted above, the rear cover of an electronic device may implement thermal exhaust vents that utilize thermal vent grills, which also need to comply with safety regulations as noted herein. The adjustable thermal vent assemblies as discussed herein may also be implemented for such thermal exhaust vents, which may likewise comprise any suitable combination of mechanically-actuated and/or electromechanically-actuated adjustable thermal vent assemblies. However, given that many electronic components have knowledge of the angle of the display cover, the use of electromechanically-actuated adjustable thermal vent assemblies for the rear cover thermal exhaust vents may be particularly useful. Thus, an electronic device may implement any suitable combination of mechanically-actuated and/or electromechanically-actuated adjustable thermal vent assemblies, with respect to both the bottom cover thermal intake vents and the rear cover thermal exhaust vents. To provide a non-limiting and illustrative scenario, the thermal intake vents may implement mechanically-actuated and/or electromechanically actuated adjustable thermal vent assemblies, whereas the thermal exhaust vents may implement only electromechanically-actuated adjustable thermal vent assemblies.

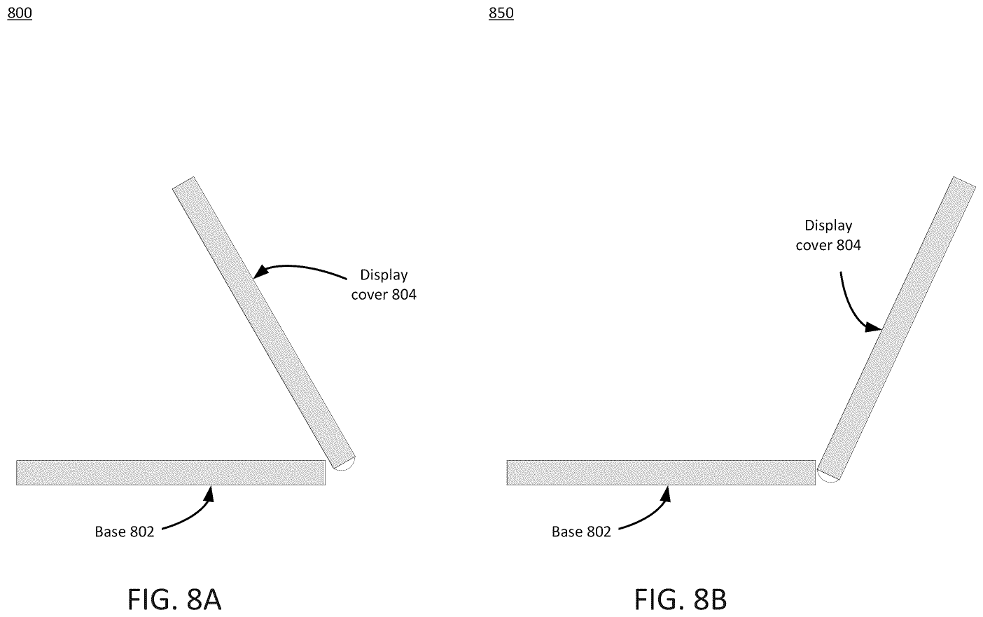

Turning now to FIGS. 8A and 8B, the use of electromechanically-actuated adjustable thermal vent assemblies is described for the rear cover thermal exhaust vents. FIG. 8A illustrates an implementation of an adjustable thermal vent assembly for a rear cover of an electronic device for a scenario in which the triggering condition has not been met. FIG. 8B, on the other hand, illustrates an implementation of the adjustable thermal vent assembly for a rear cover of an electronic device for a scenario in which the triggering condition has been met.

FIGS. 8A and 8B illustrate different use cases for an electronic device comprising a laptop, which comprises a base 802 and a display cover 804. The base 802 may include a bottom cover that is identified with the electronic device chassis 212 as discussed herein. The base 802 may comprise one or more adjustable thermal vent assemblies, such as the mechanically- and/or electromechanically-actuated adjustable thermal vent assemblies described herein.

For the use case as shown in FIG. 8A, the angle formed between the base 802 and the display cover 804 ensures that access to the rear cover thermal exhaust vents is not impeded, and thus the movable shutter plate 202 identified with each adjustable thermal vent assembly of the thermal exhaust vents in the rear cover is in its default position, i.e. resulting in a lower OAR value. However, for the use case as shown in FIG. 8B, the angle formed between the base 802 and the display cover 804 cause the rear cover thermal exhaust vents to be obstructed, and thus the movable shutter plates 202 identified with each adjustable thermal vent assembly of the thermal exhaust vents in the rear cover are actuated to the second position, resulting in a higher OAR value.

The triggering condition for the movable shutter plates 202 identified with each adjustable thermal vent assembly in the base 802 may be defined in various ways. In some non-limiting and illustrative scenarios, additional sensors may not be required to determine whether the triggering condition is met. This is because many computing systems have knowledge of the angle of the display cover 804 during use from readily available system-level and/or operating system (OS) data. Additionally or alternatively, such angle information may be readily available from an existing embedded controller (EC) in the electronic device, an integrated sensor hub (ISH), etc.

Thus, a predetermined range of angles between the display cover 804 and the base 802 may be identified that results in the obstruction of the rear cover thermal exhaust vents. As a result, the triggering condition is met for the actuation of the movable plate assembly 202 to the second, higher OAR position when the display cover 804 is determined to be within this predetermined range of angles. The processing circuitry of the electronic device may in such scenarios, generate the control signals that are transmitted to the electromechanical actuator 604.2 for each adjustable thermal vent assembly in response to the current angle of the display cover 804 being within the predetermined range of angles.

Additionally or alternatively, the base 802 may implement sensors to determine when the display cover 804 obstructs the rear cover thermal exhaust vents. Thus, the processing circuitry of the electronic device may in such scenarios, generate the control signals that are transmitted to the electromechanical actuator 604.2 for each adjustable thermal vent assembly in response to the sensor data indicating that the display cover 804 is obstructing the rear cover thermal exhaust vents. These sensors may comprise the proximity sensors as discussed herein with respect to the bottom cover adjustable thermal vent assemblies. Alternatively, the sensors may comprise other suitable sensors that may output sensor data indicative of the current angle of the display cover 804. This may include a resistive-base (potentiometer), magnetic and inductive sensors (hall-effect, eddy current sensors, resolvers), optical, electric encoders, etc.

In any event, when the angle of the display cover 804 is detected as obstructing the rear cover thermal exhaust vents, the movable shutter plates 202 identified with each adjustable thermal vent assembly in the base 802 are actuated to the second position, resulting in the higher OAR value. Of course, regardless of the particular manner in which the use case is detected, the processing circuitry of the electronic device may generate the control signals that are transmitted to the electromechanical actuator 604.2 in response to different use cases to actuate the movable shutter plate 202 between the default and the second, higher OAR position, as noted herein.

In other non-limiting and illustrative scenarios, additional or alternate sensors may be implemented by the electronic device to detect one or more triggering conditions, resulting in an increased OAR value as discussed herein, and the loss of the respective one or more triggering conditions, resulting in a return to the default, lower OAR value as noted herein. That is, regardless of the number and/or type of sensors used, the electromechanically-actuated adjustable thermal vent assemblies as described herein may advantageously rely on any suitable type of sensor data to identify a current use case. Various use cases may be mapped to corresponding triggering conditions, such as the placement of the electronic device onto the surface 402, the display cover 804 blocking access to a rear cover thermal vent, etc. Such use cases may result in the actuation of the movable shutter plate 202 to increase the OAR, as noted above.

Moreover, additional use cases may be mapped to trigger the default OAR, i.e. the actuation of the movable shutter plate 202 back to its default position. Thus, it is noted that the term “triggering condition” is primarily used herein to describe a use case and/or specific conditions that result in an actuation of the movable shutter plate from the default position to a new position that increases the OAR. However, it is further noted that the detection of any change in the current use case and/or specific conditions that result in an actuation of the movable shutter plate 202 from its current position to a new position may likewise constitute a triggering condition. For instance, the change in the use case to a new use case, such as a removal of the electronic device from the surface 402, closure of the display cover 804, etc., may also represent a triggering condition with respect to the current position of the movable actuator 202 from the second, higher OAR position back to the default, lower OAR position as noted herein.

To this end, it may be particularly useful to implement sensor data to determine these various triggering conditions, which may include the use of any of the sensors as discussed above. Additionally or alternatively, and to provide additional non-limiting and illustrative scenarios, the sensors may include other types of sensors that generate any suitable type of sensor data that is analyzed to detect a current use case, which may then be used to determine the current position for the movable shutter plate 202. Thus, the sensors may include accelerometers, motion sensors, orientation sensors, thermal sensors, etc. The sensor data generated by these sensors may then be continuously or periodically monitored and analyzed to detect a change in the current use case, such as movement of the electronic device from the surface 402 or into a new orientation that changes accessibility to a respective thermal vent.

### II. Thermal Simulation Results

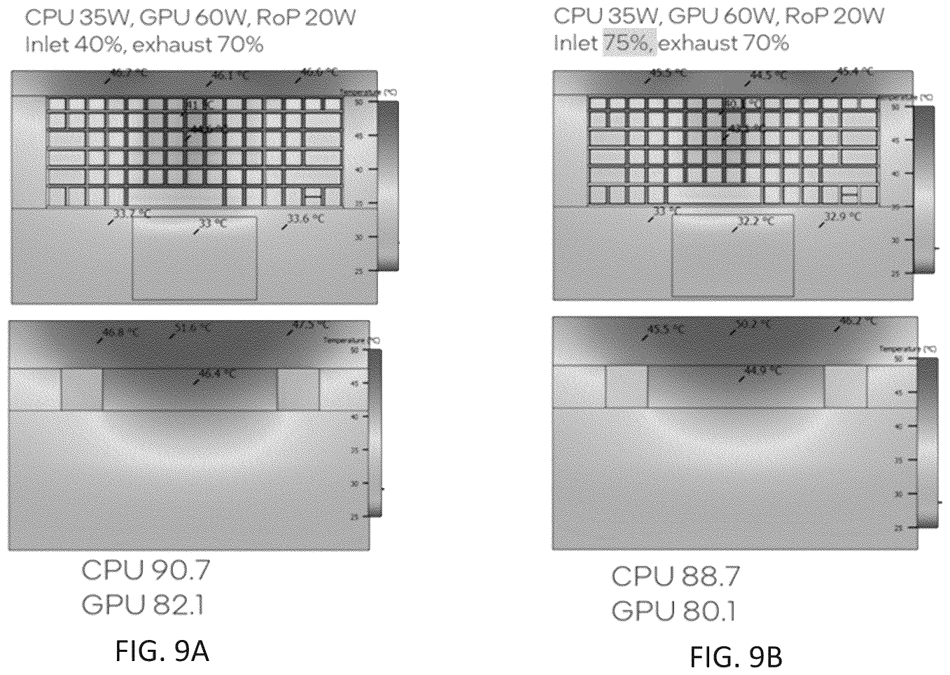

FIGS. 9A and 9B illustrate the result of thermal simulations for an adjustable thermal vent assembly, in accordance with the disclosure. FIGS. 9A and 9B show thermal simulations for a laptop implementing the adjustable thermal vent assemblies for two thermal intake vents on the bottom cover and using standard thermal exhaust vents on the rear cover. The laptop configuration for this thermal simulation has a TCP of 115W (35W CPU, 60W GPU, 20W ROP), and the ambient temperature is set to 25 degrees C. For FIG. 9A, the OAR for the adjustable thermal vent assemblies for the thermal intake vents is set to 40% (i.e. the default value), whereas the OAR for the thermal exhaust vents on the rear cover is 70%. For FIG. 9B, the OAR for the adjustable thermal vent assemblies for the thermal intake vents is increased to 75% (i.e. the second position for the movable shutter 202). As can be observed by way of a comparison of FIGS. 9A and 9B, with the increased OAR, the skin temperature of the chassis was reduced by 1.5 degrees C. for the same system on a chip (SoC) power (the lower the skin temperature, the better the user experience). Alternatively, if the same skin temperature of the chassis as the original design was maintained, the increased OAR would yield a 6 W increase in SoC power, i.e. the SoC performance could be increased.

Thus, it is noted that the adjustable thermal vent assemblies as discussed herein not only provide advantages with respect to providing an increased OAR for thermal vents, but do so without impacting chassis size and/or shape, and have a minimal or no z-dimension impact. Furthermore, the adjustable thermal vent assemblies as discussed herein provide a low-cost solution, improve thermal/SOC performance.

### III. An Electronic Device

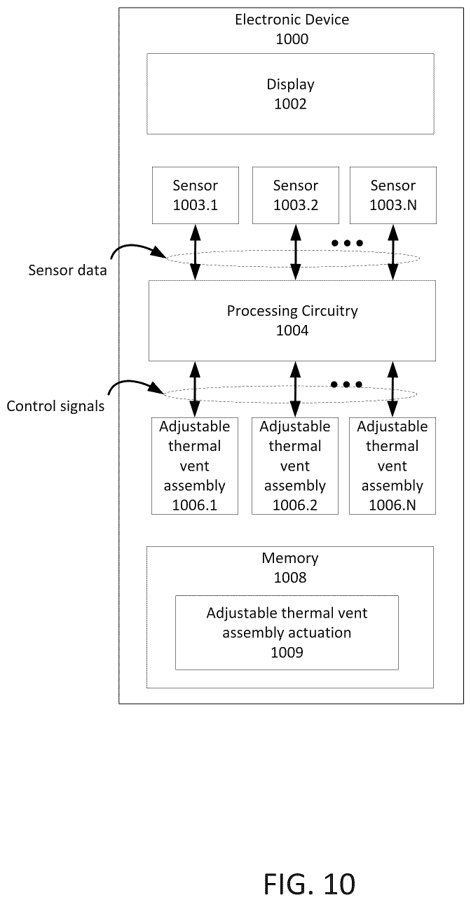

FIG. 10 illustrates an electronic device, in accordance with the disclosure. The electronic device 1000 may be identified with any suitable type of device that implements one or more of the adjustable thermal vent assemblies as discussed herein. The electronic device 1000 may be identified with any suitable type of electronic device in which thermal vents are utilized. Thus, the electronic device 1000 may be identified with a wireless device, a user equipment (UE), a mobile phone, a laptop computer, a tablet, a wearable device, etc.

The electronic device 1000 may comprise a display 1002, which may form part of a display assembly such as the display cover 804 as discussed above. The display 1002 may be implemented as or form part of any suitable type of display assembly such as a light-emitting diode (LED) display, a liquid crystal display (LDC), an organic LED display, a Twisted Nematic (TN) display, an In-Plane Switching (IPS) display, etc. The display cover 804 associated with the display 1002 may comprise one or more thermal vents, such as thermal exhaust vents, each being identified with a respective adjustable thermal vent assembly as discussed herein.

The electronic device 1000 may comprise any suitable number of sensors 1003.1-1003.N. Each of the sensors 1003.1-1003.N may be implemented as any suitable type of sensor as discussed herein, each being configured to generate sensor data in accordance with a particular type of sensor measurement. The sensors 1003.1-1003.N may be identified with existing sensors of the electronic device 1000 (such as an ISH), or dedicated sensors used for the actuation of the adjustable thermal vent assemblies, as discussed herein. Each of the sensors 1003.1-1003.N is configured to generate sensor data as noted above, which may be transmitted to the processing circuitry 1004.

The electronics device 1000 may further comprise processing circuitry 1004, which may be configured as any suitable number and/or type of computer processors, and which may function to control the electronic device 1000 and/or other components of the electronic device 1000, such as the actuation of the adjustable thermal vent assemblies 1006.1-1006.N when implemented as electromechanically-actuated adjustable thermal vent assemblies. The processing circuitry 1004 may be identified with one or more processors (or suitable portions thereof) implemented by the electronic device 1000. The processing circuitry 1004 may be identified with one or more processors such as a host processor, a microcontroller, a digital signal processor, one or more microprocessors, a central processing unit (CPU), graphics processors such as a graphics processing unit (GPU), baseband processors, microcontrollers, an application-specific integrated circuit (ASIC), part (or the entirety of) a field-programmable gate array (FPGA), etc.

The processing circuitry 1004 may be configured to carry out instructions to perform arithmetical, logical, and/or input/output (I/O) operations, and/or to control the operation of one or more components of electronic device 1000 to perform various functions as described herein. The processing circuitry 1004 may include one or more microprocessor cores, memory registers, buffers, clocks, etc., and may generate electronic control signals associated with the components of the electronic device 1000 to control and/or modify the operation of these components. The processing circuitry 1004 may communicate with and/or control functions associated with the memory 1008, as well as any other components of the electronic device 1000. Thus, the processing circuitry 1004 may control or cause other components to control the actuation of the movable shutter plate 202 of the adjustable thermal vent assemblies 1006.1-1006.N via actuation of a respective electromechanical actuator 604.2 in response to one or more triggering conditions being met, as discussed herein.

The electronic device 1000 comprises any suitable number N of adjustable thermal vent assemblies 1006.1-1006.N. These adjustable thermal vent assemblies 1006.1-1006.N may comprise any combination of the mechanically-actuated adjustable thermal vent assemblies as discussed above with respect to FIGS. 2, 3A-3B, 4A-4B, and 5A-5B and/or the electromechanically-actuated adjustable thermal vent assemblies as discussed above with respect to FIGS. 6A-6B. Of course, the processing circuitry 1004 may control the electromechanically-actuated adjustable thermal vent assemblies based upon the generated sensor data, whereas the mechanically-actuated adjustable thermal vent assemblies may be controlled in a mechanical fashion, as noted herein.

The memory 1008 is configured to store data and/or instructions such that, when executed by the processing circuitry 1004, cause the electronic device 1000 to perform various functions such as controlling, monitoring, and/or regulating the operation of the electronic device 1000, analyzing the sensor data, determining whether a triggering condition has been met, generating the control signals for the actuation of the adjustable thermal vent assemblies 1006.1-1006.N, etc., as discussed in further detail herein. The memory 1008 may be implemented as any suitable type of volatile and/or non-volatile memory, including read-only memory (ROM), random access memory (RAM), flash memory, a magnetic storage media, an optical disc, erasable programmable read only memory (EPROM), programmable read only memory (PROM), etc. The memory 1008 may be non-removable, removable, or a combination of both. The memory 1008 may be implemented as a non-transitory computer readable medium storing one or more executable instructions such as logic, algorithms, code, etc. The instructions, logic, code, etc., stored in the memory 1008 are represented by the various modules as shown. The processing circuitry 1004 may execute the instructions stored in the memory 1008, which are represented as the various modules and further discussed below, to enable any of the techniques as described herein to be functionally realized.

The adjustable thermal vent assembly actuation module 1009 may store computer-readable instructions that, when executed by the processing circuitry 1004, enable the processing circuitry 1004 to perform any of the functions as described herein with respect to the control of the position of the movable shutter plate 202 with respect to each one of the adjustable thermal vent assemblies 1006.1-1006.N that implements electromechanically-controlled actuation, as discussed herein. Thus, the processing circuitry 1004 may execute the instructions stored in the adjustable thermal vent assembly actuation module 1009 to receive and analyze the sensor data input data from any suitable components of the electronic device 1000, to determine whether one or more triggering conditions have been met, to generate control signals to switch the position of the movable shutter plate 202 with respect to each one of the adjustable thermal vent assemblies 1006.1-1006.N, etc.

### IV. A Process Flow

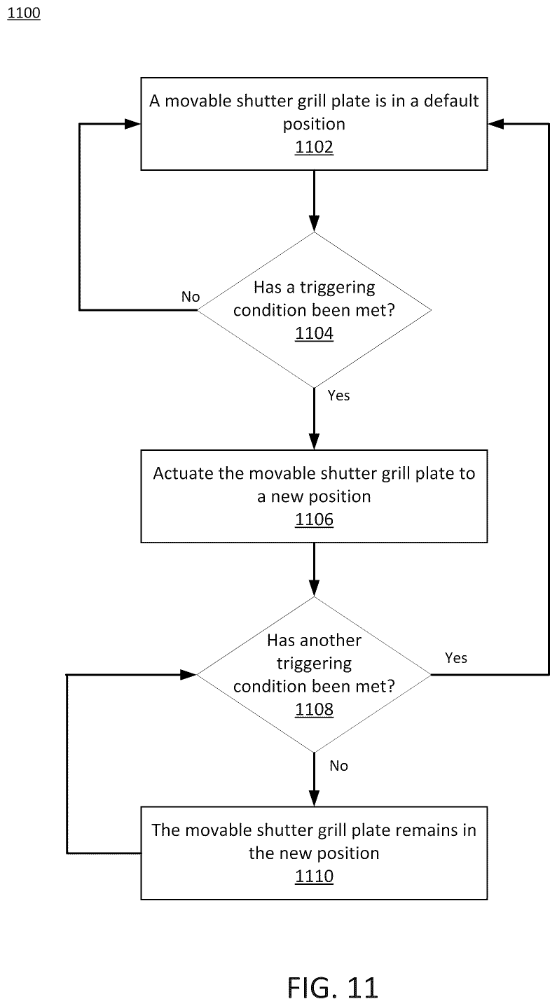

FIG. 11 illustrates a process flow, in accordance with the disclosure. With reference to FIG. 11, the flow 1100 may comprise a process flow that is executed by and/or otherwise associated with one or more processors and/or components identified with any suitable electronic device. The one or more processors and/or components may be identified with the processing circuitry 1004 as discussed herein with respect to FIG. 10, and may be implemented via one or more processors executing instructions stored on any suitable computer-readable storage medium, such as the memory 1008. Alternatively, the flow 1100 may be performed by way of mechanical actuation. The flow 1100 may include alternate or additional processes that are not shown for purposes of brevity, and may be performed in a different order than those shown.

Flow 1100 may begin when the movable shutter plate 202 is in an initial, default position (block 1102). This may include, in a non-limiting and illustrative scenario, the movable shutter plate 202 of a respective adjustable thermal vent assembly as discussed herein being in the default position associated with a lower OAR value.

The flow 1100 may further comprise determining (block 1104) whether a triggering condition has been met. As noted above, this may include a mechanical actuation that results in a use case being met, such as the placement of the electronic device 1000 onto the surface 402, resulting in compression of the triggering mechanism 206. Alternatively, this may comprise an analysis of sensor data via the processing circuitry 1004 as discussed herein, resulting in a determination that the triggering condition has been met. Again, this triggering condition may comprise any suitable condition that results in a use case in which the respective adjustable thermal vent assembly is no longer accessible.

If the triggering condition has been met (block 1104, Yes), then the process flow 1100 may proceed to block 1106. However, if the triggering condition is not met (block 1104, No), then the movable shutter plate 202 remains (block 1102) in its initial, default position associated with the lower OAR value. Thus, the process flow 1100 remains in a “loop” represented by the blocks 1102, 1104 until the triggering condition has been met.

Once the triggering condition has been met, the process flow 1100 comprises actuating (block 1106) the movable shutter plate 202 of a respective adjustable thermal vent assembly. That is, the movable shutter plate 202 is actuated to a new position in which the OAR value is increased, as noted above.

The process flow 1100 then continues to determine (block 1108) whether another trigger condition has been met, which may be the absence of and/or cessation of the initial triggering condition. Thus, this additional triggering condition may comprise any suitable condition that results in a use case in which the respective adjustable thermal vent assembly is once again accessible.

If the additional triggering condition is met (block 1108, Yes), then the process flow 1100 may revert back to block 1102 such that the movable shutter plate 202 is returned (such as via actuation or a lack of actuation allowing the movable shutter plate to return) to its default position. However, if the additional triggering condition not met (block 1108, No), then the movable shutter plate 202 remains in the new, higher OAR position (block 1110). Thus, the process flow 1100 remains in the higher OAR “loop” represented by the blocks 1108, 1110 until the additional triggering condition has been met, which indicates that the current use case has transitioned to one in which the respective adjustable thermal vent assembly is once again accessible.

### V. General Configuration of an Adjustable Thermal Vent Assembly

An adjustable thermal vent assembly is provided. The adjustable thermal vent assembly comprises a movable shutter grill plate configured to fit over a thermal vent grill, the thermal vent grill comprises a first grating having a first grating spacing, and the movable shutter grill plate comprises a second grating having a second grating spacing; and a triggering mechanism configured, in response to a triggering condition being met, to move the movable shutter grill plate from a first position to a second position. When the movable shutter grill plate is in the first position, the second grating is interspaced between the first grating to form a first overlapping grating spacing, and when the movable shutter grill plate is in the second position, the first overlapping grating spacing is increased to form a larger, second overlapping grating spacing. In addition or in alternative to and in any combination with the optional features previously explained in this paragraph, the adjustable thermal vent assembly further includes a latch mechanism coupled to the movable shutter grill plate, and the triggering mechanism is configured to actuate the latch mechanism to move the movable shutter grill plate from the first position to the second position. In addition or in alternative to and in any combination with the optional features previously explained in this paragraph, the first grating spacing and the second grating spacing are associated with a first and a second grating pitch, respectively of greater than about one millimeter, and the first overlapping grating spacing is associated with an overlapping grating pitch of less than about one millimeter. In addition or in alternative to and in any combination with the optional features previously explained in this paragraph, the first grating spacing and the second grating spacing are associated with a first and a second grating pitch, respectively, which are equal to one another. In addition or in alternative to and in any combination with the optional features previously explained in this paragraph, when the movable shutter grill plate is in the second position, the second grating is aligned with the first grating. In addition or in alternative to and in any combination with the optional features previously explained in this paragraph, the adjustable thermal vent assembly further includes a latch mechanism coupled to the movable shutter grill plate, the latch mechanism comprising a spring configured to actuate the movable shutter grill plate to the first position when the triggering condition is not met. In addition or in alternative to and in any combination with the optional features previously explained in this paragraph, the triggering mechanism comprises a movable trigger assembly configured to actuate the latch mechanism to move in response to a compressible force being applied to the triggering mechanism, and the triggering condition is met when the compressible force is applied to the movable trigger assembly exceeding a predetermined threshold value. In addition or in alternative to and in any combination with the optional features previously explained in this paragraph, the adjustable thermal vent assembly further includes a latch mechanism coupled to the movable shutter grill plate, the latch mechanism comprising an electromechanical actuator configured to actuate the movable shutter grill plate to the second position when the triggering condition is met. In addition or in alternative to and in any combination with the optional features previously explained in this paragraph, the triggering mechanism comprises a proximity sensor configured to generate sensor data, the electromechanical actuator is configured to actuate the latch mechanism to move the movable shutter grill plate to the first position and to the second position based upon the sensor data, and the triggering condition is met when the sensor data indicates that the proximity sensor is within a threshold distance of an object. In addition or in alternative to and in any combination with the optional features previously explained in this paragraph, the thermal vent grill is disposed on a bottom cover or a rear cover of a laptop computer.

### VI. General Configuration of an Electronic Device

An electronic device, is provided. The electronic device comprises a thermal vent grill comprising a first grating, the thermal vent grill providing an airflow opening for the electronic device that is associated with an open air ratio (OAR); a movable shutter grill plate disposed over the thermal vent grill, the movable shutter grill plate comprising a second grating; and a triggering mechanism configured, in response to a triggering condition being met, to move the movable shutter grill plate from a first position to a second position, and when the movable shutter grill plate is moved from the first position to the second position, the OAR is increased. In addition or in alternative to and in any combination with the optional features previously explained in this paragraph, the electronic device further includes a latch mechanism coupled to the movable shutter grill plate, the triggering mechanism being configured to actuate the latch mechanism to move movable shutter grill plate from the first position to the second position. In addition or in alternative to and in any combination with the optional features previously explained in this paragraph, when the movable shutter grill plate is in the first position, the second grating is interspaced between the first grating to form a first overlapping grating spacing, and when the movable shutter grill plate is in the second position, the first overlapping grating spacing is increased to form a larger, second overlapping grating spacing. In addition or in alternative to and in any combination with the optional features previously explained in this paragraph, the first grating comprises a first grating spacing having a first grating pitch, the second grating comprises a second grating spacing having a second grating pitch, the first grating pitch and the second grating pitch are greater than about one millimeter, and the first overlapping grating spacing has an overlapping grating pitch of less than about one millimeter. In addition or in alternative to and in any combination with the optional features previously explained in this paragraph, the first grating comprises a first grating spacing having a first grating pitch, the second grating comprises a second grating spacing having a second grating pitch, and the first grating pitch and the second grating pitch are equal to one another. In addition or in alternative to and in any combination with the optional features previously explained in this paragraph, when the movable shutter grill plate is in the second position, the second grating is aligned with the first grating. In addition or in alternative to and in any combination with the optional features previously explained in this paragraph, the electronic device further includes a latch mechanism coupled to the movable shutter grill plate, the latch mechanism comprising a spring configured to actuate the movable shutter grill plate to the first position when the triggering condition is not met. In addition or in alternative to and in any combination with the optional features previously explained in this paragraph, the triggering mechanism comprises a movable trigger assembly configured to actuate the latch mechanism to move in response to a compressible force being applied to the triggering mechanism, and the triggering condition is met when the compressible force is applied to the triggering mechanism exceeding a predetermined threshold value. In addition or in alternative to and in any combination with the optional features previously explained in this paragraph, the electronic device further includes a latch mechanism coupled to the movable shutter grill plate, the latch mechanism comprising an electromechanical actuator configured to actuate the movable shutter grill plate to the second position when the triggering condition is met. In addition or in alternative to and in any combination with the optional features previously explained in this paragraph, the triggering mechanism comprises a proximity sensor configured to generate sensor data, and the electromechanical actuator is configured to actuate the latch mechanism to move the movable shutter grill plate to the first position and the second position based upon the sensor data, and the triggering condition is met when the sensor data indicates that the proximity sensor is within a threshold distance of an object.

### EXAMPLES

The following examples pertain to various techniques of the present disclosure.

An example (e.g. example 1) is directed to an adjustable thermal vent assembly, comprising: a movable shutter grill plate configured to fit over a thermal vent grill, wherein the thermal vent grill comprises a first grating having a first grating spacing, and wherein the movable shutter grill plate comprises a second grating having a second grating spacing; and a triggering mechanism configured, in response to a triggering condition being met, to move the movable shutter grill plate from a first position to a second position, wherein, when the movable shutter grill plate is in the first position, the second grating is interspaced between the first grating to form a first overlapping grating spacing, and wherein, when the movable shutter grill plate is in the second position, the first overlapping grating spacing is increased to form a larger, second overlapping grating spacing.

Another example (e.g. example 2), relates to a previously-described example (e.g. example 1), further comprising: a latch mechanism coupled to the movable shutter grill plate, wherein the triggering mechanism is configured to actuate the latch mechanism to move the movable shutter grill plate from the first position to the second position.

Another example (e.g. example 3) relates to a previously-described example (e.g. one or more of examples 1-2), wherein: the first grating spacing and the second grating spacing are associated with a first and a second grating pitch, respectively of greater than about one millimeter, and the first overlapping grating spacing is associated with an overlapping grating pitch of less than about one millimeter.

Another example (e.g. example 4) relates to a previously-described example (e.g. one or more of examples 1-3), wherein: the first grating spacing and the second grating spacing are associated with a first and a second grating pitch, respectively, which are equal to one another.

Another example (e.g. example 5) relates to a previously-described example (e.g. one or more of examples 1-4), wherein, when the movable shutter grill plate is in the second position, the second grating is aligned with the first grating.

Another example (e.g. example 6) relates to a previously-described example (e.g. one or more of examples 1-5), further comprising: a latch mechanism coupled to the movable shutter grill plate, the latch mechanism comprising a spring configured to actuate the movable shutter grill plate to the first position when the triggering condition is not met.

Another example (e.g. example 7) relates to a previously-described example (e.g. one or more of examples 1-6), wherein the triggering mechanism comprises a movable trigger assembly configured to actuate the latch mechanism to move in response to a compressible force being applied to the triggering mechanism, and wherein the triggering condition is met when the compressible force is applied to the movable trigger assembly exceeding a predetermined threshold value.

Another example (e.g. example 8) relates to a previously-described example (e.g. one or more of examples 1-7), further comprising: a latch mechanism coupled to the movable shutter grill plate, the latch mechanism comprising an electromechanical actuator configured to actuate the movable shutter grill plate to the second position when the triggering condition is met.

Another example (e.g. example 9) relates to a previously-described example (e.g. one or more of examples 1-8), wherein: the triggering mechanism comprises a proximity sensor configured to generate sensor data, the electromechanical actuator is configured to actuate the latch mechanism to move the movable shutter grill plate to the first position and to the second position based upon the sensor data, and the triggering condition is met when the sensor data indicates that the proximity sensor is within a threshold distance of an object.

Another example (e.g. example 10) relates to a previously-described example (e.g. one or more of examples 1-9), wherein the thermal vent grill is disposed on a bottom cover or a rear cover of a laptop computer.

An example (e.g. example 11) is directed to an electronic device, comprising: a thermal vent grill comprising a first grating, the thermal vent grill providing an airflow opening for the electronic device that is associated with an open air ratio (OAR); a movable shutter grill plate disposed over the thermal vent grill, the movable shutter grill plate comprising a second grating; and a triggering mechanism configured, in response to a triggering condition being met, to move the movable shutter grill plate from a first position to a second position, wherein, when the movable shutter grill plate is moved from the first position to the second position, the OAR is increased.

Another example (e.g. example 12), relates to a previously-described example (e.g. example 11), further comprising: a latch mechanism coupled to the movable shutter grill plate, wherein the triggering mechanism is configured to actuate the latch mechanism to move movable shutter grill plate from the first position to the second position.

Another example (e.g. example 13) relates to a previously-described example (e.g. one or more of examples 11-12), wherein: when the movable shutter grill plate is in the first position, the second grating is interspaced between the first grating to form a first overlapping grating spacing, and wherein, when the movable shutter grill plate is in the second position, the first overlapping grating spacing is increased to form a larger, second overlapping grating spacing.

Another example (e.g. example 14) relates to a previously-described example (e.g. one or more of examples 11-13), wherein: the first grating comprises a first grating spacing having a first grating pitch, the second grating comprises a second grating spacing having a second grating pitch, the first grating pitch and the second grating pitch are greater than about one millimeter, and the first overlapping grating spacing has an overlapping grating pitch of less than about one millimeter.

Another example (e.g. example 15) relates to a previously-described example (e.g. one or more of examples 11-14), wherein: the first grating comprises a first grating spacing having a first grating pitch, the second grating comprises a second grating spacing having a second grating pitch, and the first grating pitch and the second grating pitch are equal to one another.

Another example (e.g. example 16) relates to a previously-described example (e.g. one or more of examples 11-15), wherein, when the movable shutter grill plate is in the second position, the second grating is aligned with the first grating.

Another example (e.g. example 17) relates to a previously-described example (e.g. one or more of examples 11-16), further comprising: a latch mechanism coupled to the movable shutter grill plate, the latch mechanism comprising a spring configured to actuate the movable shutter grill plate to the first position when the triggering condition is not met.

Another example (e.g. example 18) relates to a previously-described example (e.g. one or more of examples 11-17), wherein the triggering mechanism comprises a movable trigger assembly configured to actuate the latch mechanism to move in response to a compressible force being applied to the triggering mechanism, and wherein the triggering condition is met when the compressible force is applied to the triggering mechanism exceeding a predetermined threshold value.

Another example (e.g. example 19) relates to a previously-described example (e.g. one or more of examples 11-18), further comprising: a latch mechanism coupled to the movable shutter grill plate, the latch mechanism comprising an electromechanical actuator configured to actuate the movable shutter grill plate to the second position when the triggering condition is met.

Another example (e.g. example 20) relates to a previously-described example (e.g. one or more of examples 11-19), wherein: the triggering mechanism comprises a proximity sensor configured to generate sensor data, and the electromechanical actuator is configured to actuate the latch mechanism to move the movable shutter grill plate to the first position and the second position based upon the sensor data, and the triggering condition is met when the sensor data indicates that the proximity sensor is within a threshold distance of an object.

An example (e.g. example 21) is directed to an adjustable thermal vent assembly, comprising: a movable shutter means for fitting over a thermal vent grill, wherein the thermal vent grill comprises a first grating having a first grating spacing, and wherein the movable shutter means comprises a second grating having a second grating spacing; and a triggering means for, in response to a triggering condition being met, moving the movable shutter grill plate from a first position to a second position, wherein, when the movable shutter means is in the first position, the second grating is interspaced between the first grating to form a first overlapping grating spacing, and wherein, when the movable shutter means is in the second position, the first overlapping grating spacing is increased to form a larger, second overlapping grating spacing.

Another example (e.g. example 22), relates to a previously-described example (e.g. example 21), further comprising: a latching means coupled to the movable shutter means, wherein the triggering means actuates the latch mechanism to move the movable shutter means from the first position to the second position.

Another example (e.g. example 23) relates to a previously-described example (e.g. one or more of examples 21-22), wherein: the first grating spacing and the second grating spacing are associated with a first and a second grating pitch, respectively of greater than about one millimeter, and the first overlapping grating spacing is associated with an overlapping grating pitch of less than about one millimeter.

Another example (e.g. example 24) relates to a previously-described example (e.g. one or more of examples 21-23), wherein: the first grating spacing and the second grating spacing are associated with a first and a second grating pitch, respectively, which are equal to one another.

Another example (e.g. example 25) relates to a previously-described example (e.g. one or more of examples 21-24), wherein, when the movable shutter grill plate is in the second position, the second grating is aligned with the first grating.

Another example (e.g. example 26) relates to a previously-described example (e.g. one or more of examples 21-25), further comprising: a latching means coupled to the movable shutter means, the latching means comprising a spring configured to actuate the movable shutter means to the first position when the triggering condition is not met.

Another example (e.g. example 27) relates to a previously-described example (e.g. one or more of examples 21-26), wherein the triggering means comprises a movable trigger assembly configured to actuate the latching means to move in response to a compressible force being applied to the triggering means, and wherein the triggering condition is met when the compressible force is applied to the movable trigger assembly exceeding a predetermined threshold value.

Another example (e.g. example 28) relates to a previously-described example (e.g. one or more of examples 21-27), further comprising: a latching means coupled to the movable shutter means, the latching means comprising an electromechanical actuator configured to actuate the movable shutter means to the second position when the triggering condition is met.

Another example (e.g. example 29) relates to a previously-described example (e.g. one or more of examples 21-28), wherein: the triggering means comprises a proximity sensor configured to generate sensor data, the electromechanical actuator is configured to actuate the latching means to move the movable shutter means to the first position and to the second position based upon the sensor data, and the triggering condition is met when the sensor data indicates that the proximity sensor is within a threshold distance of an object.

Another example (e.g. example 30) relates to a previously-described example (e.g. one or more of examples 21-29), wherein the thermal vent grill is disposed on a bottom cover or a rear cover of a laptop computer.

An example (e.g. example 31) is directed to an electronic device, comprising: a thermal vent grill comprising a first grating, the thermal vent grill providing an airflow opening for the electronic device that is associated with an open air ratio (OAR); a movable shutter means disposed over the thermal vent grill, the movable shutter means comprising a second grating; and a triggering means for, in response to a triggering condition being met, moving the movable shutter means from a first position to a second position, wherein, when the movable shutter means is moved from the first position to the second position, the OAR is increased.

Another example (e.g. example 32), relates to a previously-described example (e.g. example 31), further comprising: a latching means coupled to the movable shutter means, wherein the triggering means is configured to actuate the latching means to move movable shutter means from the first position to the second position.

Another example (e.g. example 33) relates to a previously-described example (e.g. one or more of examples 31-32), wherein: when the movable shutter means is in the first position, the second grating is interspaced between the first grating to form a first overlapping grating spacing, and wherein, when the movable shutter means is in the second position, the first overlapping grating spacing is increased to form a larger, second overlapping grating spacing.

Another example (e.g. example 34) relates to a previously-described example (e.g. one or more of examples 31-33), wherein: the first grating comprises a first grating spacing having a first grating pitch, the second grating comprises a second grating spacing having a second grating pitch, the first grating pitch and the second grating pitch are greater than about one millimeter, and the first overlapping grating spacing has an overlapping grating pitch of less than about one millimeter.

Another example (e.g. example 35) relates to a previously-described example (e.g. one or more of examples 31-34), wherein: the first grating comprises a first grating spacing having a first grating pitch, the second grating comprises a second grating spacing having a second grating pitch, and the first grating pitch and the second grating pitch are equal to one another.

Another example (e.g. example 36) relates to a previously-described example (e.g. one or more of examples 31-35), wherein, when the movable shutter means is in the second position, the second grating is aligned with the first grating.

Another example (e.g. example 37) relates to a previously-described example (e.g. one or more of examples 31-36), further comprising: a latching means coupled to the movable shutter means, the latching means comprising a spring configured to actuate the movable shutter means to the first position when the triggering condition is not met.

Another example (e.g. example 38) relates to a previously-described example (e.g. one or more of examples 31-37), wherein the triggering means comprises a movable trigger assembly configured to actuate the latching means to move in response to a compressible force being applied to the triggering mechanism, and wherein the triggering condition is met when the compressible force is applied to the triggering mechanism exceeding a predetermined threshold value.

Another example (e.g. example 39) relates to a previously-described example (e.g. one or more of examples 31-38), further comprising: a latching means coupled to the movable shutter means, the latching means comprising an electromechanical actuator configured to actuate the movable shutter means to the second position when the triggering condition is met.

Another example (e.g. example 40) relates to a previously-described example (e.g. one or more of examples 31-39), wherein: the triggering means comprises a proximity sensor configured to generate sensor data, and the electromechanical actuator is configured to actuate the latching means to move the movable shutter means to the first position and the second position based upon the sensor data, and the triggering condition is met when the sensor data indicates that the proximity sensor is within a threshold distance of an object.

An apparatus as shown and described.

A method as shown and described.

### CONCLUSION

The aforementioned description will so fully reveal the general nature of the implementation of the disclosure that others can, by applying knowledge within the skill of the art, readily modify and/or adapt for various applications such specific implementations without undue experimentation and without departing from the general concept of the present disclosure.

Therefore, such adaptations and modifications are intended to be within the meaning and range of equivalents of the disclosed implementations, based on the teaching and guidance presented herein. It is to be understood that the phraseology or terminology herein is for the purpose of description and not of limitation, such that the terminology or phraseology of the present specification is to be interpreted by the skilled artisan in light of the teachings and guidance.

Each implementation described may include a particular feature, structure, or characteristic, but every implementation may not necessarily include the particular feature, structure, or characteristic. Moreover, such phrases are not necessarily referring to the same implementation. Further, when a particular feature, structure, or characteristic is described in connection with an implementation, it is submitted that it is within the knowledge of one skilled in the art to affect such feature, structure, or characteristic in connection with other implementations whether or not explicitly described.

The exemplary implementations described herein are provided for illustrative purposes, and are not limiting. Other implementations are possible, and modifications may be made to the exemplary implementations. Therefore, the specification is not meant to limit the disclosure. Rather, the scope of the disclosure is defined only in accordance with the following claims and their equivalents.

Throughout the drawings, it should be noted that like reference numbers are used to depict the same or similar elements, features, and structures, unless otherwise noted.

The terms “at least one” and “one or more” may be understood to include a numerical quantity greater than or equal to one (e.g., one, two, three, four, [ . . . ], etc.). The term “a plurality” may be understood to include a numerical quantity greater than or equal to two (e.g., two, three, four, five, [ . . . ], etc.).

The words “plural” and “multiple” in the description and in the claims expressly refer to a quantity greater than one. Accordingly, any phrases explicitly invoking the aforementioned words (e.g., “plural [elements]”, “multiple [elements]”) referring to a quantity of elements expressly refers to more than one of the said elements. The terms “group (of)”, “set (of)”, “collection (of)”, “series (of)”, “sequence (of)”, “grouping (of)”, etc., and the like in the description and in the claims, if any, refer to a quantity equal to or greater than one, i.e., one or more. The terms “proper subset”, “reduced subset”, and “lesser subset” refer to a subset of a set that is not equal to the set, illustratively, referring to a subset of a set that contains less elements than the set.

The phrase “at least one of” with regard to a group of elements may be used herein to mean at least one element from the group consisting of the elements. The phrase “at least one of” with regard to a group of elements may be used herein to mean a selection of: one of the listed elements, a plurality of one of the listed elements, a plurality of individual listed elements, or a plurality of a multiple of individual listed elements.

What is claimed is:

1. An adjustable thermal vent assembly, comprising:
a movable shutter grill plate configured to fit over a thermal vent grill,
wherein the thermal vent grill comprises a first grating having a first grating spacing, and
wherein the movable shutter grill plate comprises a second grating having a second grating spacing; and
a triggering mechanism configured, in response to a triggering condition being met, to move the movable shutter grill plate from a first position to a second position,
wherein, when the movable shutter grill plate is in the first position, the second grating is interspaced between the first grating to form a first overlapping grating spacing, and
wherein, when the movable shutter grill plate is in the second position, the first overlapping grating spacing is increased to form a larger, second overlapping grating spacing.

2. The adjustable thermal vent assembly of claim 1, further comprising:
a latch mechanism coupled to the movable shutter grill plate,
wherein the triggering mechanism is configured to actuate the latch mechanism to move the movable shutter grill plate from the first position to the second position.

3. The adjustable thermal vent assembly of claim 1, wherein:
the first grating spacing and the second grating spacing are associated with a first and a second grating pitch, respectively of greater than about one millimeter, and
the first overlapping grating spacing is associated with an overlapping grating pitch of less than about one millimeter.

4. The adjustable thermal vent assembly of claim 1, wherein:
the first grating spacing and the second grating spacing are associated with a first and a second grating pitch, respectively, which are equal to one another.

5. The adjustable thermal vent assembly of claim 1, wherein, when the movable shutter grill plate is in the second position, the second grating is aligned with the first grating.

6. The adjustable thermal vent assembly of claim 1, further comprising:
a latch mechanism coupled to the movable shutter grill plate, the latch mechanism comprising a spring configured to actuate the movable shutter grill plate to the first position when the triggering condition is not met.

7. The adjustable thermal vent assembly of claim 6, wherein the triggering mechanism comprises a movable trigger assembly configured to actuate the latch mechanism to move in response to a compressible force being applied to the triggering mechanism, and
wherein the triggering condition is met when the compressible force is applied to the movable trigger assembly exceeding a predetermined threshold value.

8. The adjustable thermal vent assembly of claim 1, further comprising:
a latch mechanism coupled to the movable shutter grill plate, the latch mechanism comprising an electromechanical actuator configured to actuate the movable shutter grill plate to the second position when the triggering condition is met.

9. The adjustable thermal vent assembly of claim 8, wherein:
the triggering mechanism comprises a proximity sensor configured to generate sensor data,
the electromechanical actuator is configured to actuate the latch mechanism to move the movable shutter grill plate to the first position and to the second position based upon the sensor data, and
the triggering condition is met when the sensor data indicates that the proximity sensor is within a threshold distance of an object.

10. The adjustable thermal vent assembly of claim 1, wherein the thermal vent grill is disposed on a bottom cover or a rear cover of a laptop computer.

11. An electronic device, comprising:
a thermal vent grill comprising a first grating, the thermal vent grill providing an airflow opening for the electronic device that is associated with an open air ratio (OAR);
a movable shutter grill plate disposed over the thermal vent grill, the movable shutter grill plate comprising a second grating; and
a triggering mechanism configured, in response to a triggering condition being met, to move the movable shutter grill plate from a first position to a second position,
wherein, when the movable shutter grill plate is moved from the first position to the second position, the OAR is increased.

12. The electronic device of claim 11, further comprising:
a latch mechanism coupled to the movable shutter grill plate,
wherein the triggering mechanism is configured to actuate the latch mechanism to move movable shutter grill plate from the first position to the second position.

13. The electronic device of claim 11, wherein:
when the movable shutter grill plate is in the first position, the second grating is interspaced between the first grating to form a first overlapping grating spacing, and
wherein, when the movable shutter grill plate is in the second position, the first overlapping grating spacing is increased to form a larger, second overlapping grating spacing.

14. The electronic device of claim 13, wherein:
the first grating comprises a first grating spacing having a first grating pitch,
the second grating comprises a second grating spacing having a second grating pitch,
the first grating pitch and the second grating pitch are greater than about one millimeter, and
the first overlapping grating spacing has an overlapping grating pitch of less than about one millimeter.

15. The electronic device of claim 11, wherein:
the first grating comprises a first grating spacing having a first grating pitch,
the second grating comprises a second grating spacing having a second grating pitch, and
the first grating pitch and the second grating pitch are equal to one another.

16. The electronic device of claim 11, wherein, when the movable shutter grill plate is in the second position, the second grating is aligned with the first grating.

17. The electronic device of claim 11, further comprising:
a latch mechanism coupled to the movable shutter grill plate, the latch mechanism comprising a spring configured to actuate the movable shutter grill plate to the first position when the triggering condition is not met.

18. The electronic device of claim 17, wherein the triggering mechanism comprises a movable trigger assembly configured to actuate the latch mechanism to move in response to a compressible force being applied to the triggering mechanism, and
wherein the triggering condition is met when the compressible force is applied to the triggering mechanism exceeding a predetermined threshold value.

19. The electronic device of claim 11, further comprising:
a latch mechanism coupled to the movable shutter grill plate, the latch mechanism comprising an electromechanical actuator configured to actuate the movable shutter grill plate to the second position when the triggering condition is met.

20. The electronic device of claim 19, wherein:
the triggering mechanism comprises a proximity sensor configured to generate sensor data, and
the electromechanical actuator is configured to actuate the latch mechanism to move the movable shutter grill plate to the first position and the second position based upon the sensor data, and
the triggering condition is met when the sensor data indicates that the proximity sensor is within a threshold distance of an object.
